(19) United States
(12) Patent Application Publication
(10) Pub. No.: US 2025/0108478 A1
(43) Pub. Date: Apr. 3, 2025

(54) SPONGE-LIKE POROUS BODY, POLISHING PAD, LIQUID ABSORBING PAD, CLEANING SPONGE, CULTIVATION SPONGE AND METHOD FOR PRODUCING SPONGE-LIKE POROUS BODY

(71) Applicant: CANON KABUSHIKI KAISHA, Tokyo (JP)

(72) Inventors: SHINJI FUKUI, Tochigi (JP); HIROKI KAKU, Tochigi (JP)

(21) Appl. No.: 18/828,100

(22) Filed: Sep. 9, 2024

(30) Foreign Application Priority Data
Sep. 28, 2023 (JP) 2023-168638

(51) Int. Cl. B24B 37/24; A01G 24/35; A01G 31/00; A47L 13/16; B01J 20/28; C23C 16/04; C23C 16/40; C23C 16/455

(52) U.S. Cl. CPC B24B 37/24; A01G 24/35; A47L 13/16; B01J 20/28045; C23C 16/045; C23C 16/402; C23C 16/45525; A01G 31/00

(57) ABSTRACT

Provided is a sponge-like porous body which is an elastic and flexible porous body, the sponge-like porous body having hydrophilic properties from the front surface portion to the inside. The sponge-like porous body has a substrate with pores, wherein an inner wall of the pores has a hydrophilic film in a region from a depth of 0% to a depth of 20% or more of the thickness of the sponge-like porous body in a thickness direction from a front surface portion to a back surface portion.

### BACKGROUND OF THE INVENTION

### Field of the Invention

The present invention relates to a sponge-like porous body, a polishing pad, a liquid absorbing pad, a cleaning sponge, a cultivation sponge and a method for producing a sponge-like porous body.

### Description of the Related Art

A sponge-like porous body is used in various situations. For example, a polishing pad for polishing a silicon wafer or glass to be flat is mostly a sponge-like porous body made of urethane. A sponge-like porous body called a waste ink absorbing pad is used in an inkjet printer to hold waste ink. In addition, various sponge-like porous bodies are commercially available for cleaning, such as dishwashing, car washing and washing human bodies. Furthermore, sponge-like porous bodies are sometimes used instead of soil for hydroponic cultivation.

Hydrophilic properties are often important for these sponge-like porous bodies. For example, in polishing pads, increased hydrophilic properties improves retention of a polishing liquid and accordingly more abrasive grains will work on the front surface of the processed product, resulting in increased polishing properties. An improvement of polishing properties not only enhance productivity of a polishing process but also has an effect of reducing a use of rare metals, which are raw materials of polishing materials. In waste ink absorbing pads, increased hydrophilicity increases ink retention and can prevent printer head contamination due to rebound or leakage from the absorbing pad. In cleaning sponges, increased hydrophilicity also improves foaming and washing effects and increases water absorption. The increased hydrophilicity of hydroponic sponges increase the retention of water and fertilizer and can efficiently supply them to plants.

A known method of improving hydrophilicity of a sponge-like porous body involves mixing a hydrophilic material with a material of the sponge-like porous body to make the porous body. For example, Japanese Patent Application Laid-Open No. 2015-120220 discloses that the hydrophilicity is increased by mixing a hydrophilic resin (epoxy resin) into a urethane polishing pad.

Another known method involves spraying a hydrophilic material on a surface of a sponge-like porous body. For example, in Yohei Kitai et al., “Improved Polishing Performance for Glass by a Novel Suede Pad Utilizing Epoxy Resin”, Journal of the Society of Mechanical Engineers (Edition C), Vol. 79, No. 808 (2013 December), pp. 5019-5028, discloses that polishing characteristics of a urethane polishing pad are improved by applying an epoxy resin, which is a hydrophilic resin, onto a surface of the polishing pad.

However, in a method disclosed in Japanese Patent Application Laid-Open No. 2015-120220, the hydrophilic material is harder than an original sponge-like porous material, and a sponge-like porous body made by mixing the hydrophilic material loses elasticity and flexibility. The loss of elasticity and flexibility leads to a decrease in the shape followability, processability, and durability of the sponge-like porous body.

Although the method disclosed in Yohei Kitai et al., “Improved Polishing Performance for Glass by a Novel Suede Pad Utilizing Epoxy Resin”, Journal of the Society of Mechanical Engineers (Edition C), Vol. 79, No. 808 (2013 December), pp. 5019-5028, allows the original sponge-like porous material to maintain elasticity and flexibility, only a vicinity of a surface of the sponge-like porous body can be hydrophilized. In a case of a polishing pad, a surface of the polishing pad is scraped off according to a polishing time. Therefore, if only a vicinity of the surface of the polishing pad is hydrophilized, hydrophilicity can only be maintained for a short period of time. In addition, other sponge-like porous bodies also have a problem that an effect of hydrophilicity is limited only to a vicinity of a surface.

Accordingly, an object of the present invention to be achieved is to provide a sponge-like porous body which is an elastic and flexible porous body, a sponge-like porous body having hydrophilic properties from the front surface portion to the inside.

### SUMMARY OF THE INVENTION

To achieve the above object, the present invention provides a sponge-like porous body having a substrate with pores, wherein an inner wall of the pores has a hydrophilic film in a region from a depth of 0% to a depth of 20% or more of a thickness of the sponge-like porous body in a thickness direction from a front surface portion to a back surface portion; and the substrate contains a foam resin.

The present invention also provides a polishing pad, a liquid absorbing pad, a cleaning sponge and a cultivation sponge, each of which includes the sponge-like porous body.

The present invention further provides a method for producing a sponge-like porous body, the method including: providing a substrate with pores; and forming a hydrophilic film on an inner wall of the pores by atomic layer deposition (ALD), wherein the substrate contains at least one selected from the group consisting of polyurethane, polyether and polyethylene.

Further features of the present invention will become apparent from the following description of exemplary embodiments with reference to the attached drawings.

### BRIEF DESCRIPTION OF THE DRAWINGS

FIG. 1A is a perspective view of a sponge-like porous body according to an embodiment of the present invention.

FIG. 1B is a schematic view of a cross-section taken along a line A-A′ of FIG. 1A.

FIG. 2A is a perspective view of a sponge-like porous body (closed-cell type) according to an embodiment of the present invention.

FIG. 2B is a schematic view of a cross-section taken along a line A-A′ of FIG. 2A.

FIG. 2C is a schematic view showing a vertical hole being made in a sponge-like porous body with a needle.

FIG. 2D is a schematic view of a cross-section taken along a line A-A′ of FIG. 2C after a vertical hole is made in the sponge-like porous body with a needle.

FIG. 3A is a schematic perspective view showing a CMP polishing step.

FIG. 3B is a side view of FIG. 3A.

FIG. 4 is a schematic perspective view of an inkjet printer.

FIG. 5 is a schematic view of an ALD film forming apparatus.

### DESCRIPTION OF THE EMBODIMENTS

Preferred embodiments of the present invention will now be described in detail in accordance with the drawings. Hereinafter, an embodiment for carrying out the present invention will be described with reference to the drawings. However, the embodiment to be described below is merely one embodiment of the present invention, and the present invention is not limited thereto. Common configurations will be described with reference to a plurality of drawings, and description of configurations which have been denoted with the same reference numerals are omitted as appropriate.

### First Embodiment

The first embodiment relates to a sponge-like porous body.

The sponge-like porous body of the present invention is a sponge-like porous body having a substrate with pores, wherein
an inner wall of the pores has a hydrophilic film in a region from a depth of 0% to a depth of 20% or more of a thickness of the sponge-like porous body in a thickness direction from a front surface portion to a back surface portion; and
the substrate contains a foam resin.

In the present specification, the sponge-like porous body refers to a flexible and elastic porous body that contains many sponge-like pores, which will be described below.

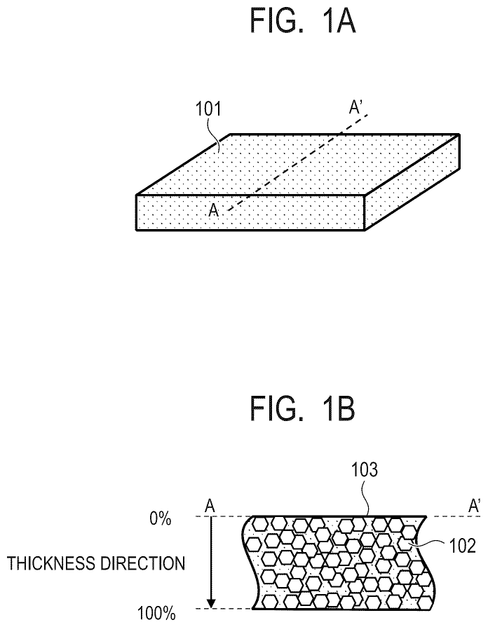

FIG. 1A illustrates a perspective view of a sponge-like porous body according to the first embodiment. FIG. 1B illustrates a schematic view of a cross-section taken along a line A-A′ of FIG. 1A. A sponge-like porous body 101 of the first embodiment has a substrate with many pores 102 therein. An inner wall of pores has a hydrophilic film (not shown) in a region from a depth of 0% to a depth of 20% or more of a thickness of the sponge-like porous body 101 in a thickness direction from a front surface portion 103 to a back surface portion of the sponge-like porous body 101. The inner wall of the pores preferably has a hydrophilic film in a region from a depth of 0% to a depth of 50% or more of the thickness of the sponge-like porous body 101 in the thickness direction from the front surface portion 103 to the back surface portion of the sponge-like porous body 101.

Here, as illustrated in FIG. 1B, the thickness direction from the front surface portion to the back surface portion of the sponge-like porous body is a direction perpendicular to the front surface portion and to the back surface portion of the sponge-like porous body, and 0% in the thickness direction represents the front surface portion of the sponge-like porous body, while 100% represents the back surface portion of the sponge-like porous body. For example, 50% in a thickness direction thus represents a center in the thickness direction. In the present invention, the front surface portion of the sponge-like porous body is, for example, an upper surface portion (top surface) of the sponge-like porous body in FIGS. 1A and 1B, while the back surface portion of the sponge-like porous body is a bottom surface portion (bottom surface) of the sponge-like porous body in FIGS. 1A and 1B.

An expression “an inner wall of pores has a hydrophilic film” herein indicates that the inner wall of all pores do not need to have a hydrophilic film, and 50% or more of pores may have a hydrophilic film. The 50% of pores means 50% or more of the number of pores present in a cross-section when the cross-section is obtained in a plane parallel to the front surface portion 103. Therefore, an expression “an inner wall of pores has a hydrophilic film in a region from a depth of 0% to a depth of 20% or more of the thickness of the sponge-like porous body in a thickness direction from a front surface portion to a back surface portion” can be interpreted as follows: 50% or more of the pores in the front surface portion 103 of the sponge-like porous body also have a hydrophilic film; and when the cross-section is obtained in a plane parallel to the front surface portion 103 at a point of a depth of 20% in the thickness direction from the front surface portion 103 of the sponge-like porous body, 50% or more of the pores appearing in the cross-section have a hydrophilic film.

The sponge-like porous body generally has elasticity and flexibility. In the present invention, an expression “the sponge-like porous body has elasticity and flexibility” indicates that hardness of the sponge-like porous body is small. As an indicator showing that the hardness of the sponge-like porous body is small, the sponge-like porous body of the present invention preferably has a hardness of 90 points or less, more preferably 80 points or less and particularly preferably 75 points or less as measured by a Type A durometer (Japanese Industrial Standards, JIS K 7215). The sponge-like porous body of the present invention preferably has a thickness of 0.1 mm or more. Particularly, the sponge-like porous body also preferably has a thickness of 0.5 mm or more for use as a polishing pad since a polishing pad which is thinner than 0.5 mm has a problem in that, for example, strength is insufficient, making the sponge-like porous body probe to tearing when fixed to a polishing tool.

Examples of a material for a substrate of the sponge-like porous body include polyurethane, polyether, polyethylene and resin materials containing these polymers. In the sponge-like porous body of the present invention, the substrate preferably contains at least one selected from the group consisting of polyurethane, polyether and polyethylene, and more preferably contains polyurethane with excellent flexibility. In the sponge-like porous body of the present invention, the substrate preferably contains a foam resin. In this configuration, the sponge-like porous body can have elasticity and flexibility. In the present invention, the elasticity and flexibility of the sponge-like porous body are represented by hardness of the sponge-like porous body, and an expression “the sponge-like porous body has elasticity and flexibility” indicates, for example, that the hardness of the sponge-like porous body is preferably 90 points or less, more preferably 80 points or less and particularly preferably 75 points or less as measured by a Type A durometer (ASKER Rubber Hardness Tester Type A, manufactured by KOBUNSHI KEIKI CO., LTD.).

In the first embodiment, hydrophilic properties are improved to an inside of the sponge-like porous body, but in order to obtain equivalent properties in a vicinity of a surface and an inside, a value of a film thickness of the hydrophilic film on the inner wall of the pores in the respective regions are preferably same in the vicinity of the surface and the inside. An average thickness of the hydrophilic film on the inner wall of the pores in a region at a depth of 0% or more and 20% or less of the thickness of the sponge-like porous body in the thickness direction from the front surface portion to the back surface portion of the sponge-like porous body is denoted as D1. An average thickness of the hydrophilic film on the inner wall of the pores in a region (a center portion) at a depth of 40% or more and 60% or less of the thickness of the sponge-like porous body in the thickness direction from the front surface portion to the back surface portion of the sponge-like porous body is denoted as D2. In this case, both D1 and D2 in the sponge-like porous body of the present invention are preferably 10 nm or more and 10 μm or less and satisfy inequality of 0.7×D2≤D1≤1.3×D2, and both D1 and D2 are more preferably 10 nm or more and 120 nm or less and satisfy inequality of 0.9×D2≤D1≤1.1×D2. Here, a reason why the values of 10 nm or more and 10 μm or less as D1 and D2 are preferred is that hydrophilic properties is poor if a value of the film thickness of the hydrophilic film is less than 10 nm, while cracking or peeling occurs due to film stress and impairs a function of the film if the value of the film thickness is more than 10 μm. The reason why the inequality of 0.7×D2≤D1≤1.3×D2 are preferred is that the equivalent hydrophilic properties can be obtained if values of the film thickness are close each other; and although openings of the pores are narrowed by the film, closer values in film thickness results in more equivalent sizes of the openings and no difference in the properties of the sponge-like porous body.

In the sponge-like porous body of the present invention, the hydrophilic film on the inner wall of the pores of the sponge-like porous body is preferably an oxide film and more preferably an inorganic oxide film. Generally, the oxide film exhibits high hydrophilicity and has a merit of high adhesion to the substrate compared to, for example, an organic film. Examples of the oxide film include SiO₂, Al₂O₃, TiO₂, Ta₂O₅, HfO₂ and RuO₂. In the sponge-like porous body of the present invention, a material of the oxide film preferably contains one or a mixture of two or more selected from the group consisting of SiO₂, Al₂O₃, TiO₂, Ta₂O₅, HfO₂ and RuO₂, and particularly preferably contains SiO₂ from a viewpoint of hydrophilicity and ease of film formation.

Furthermore, when the oxide film contains a CH group, an adhesion of the hydrophilic film is improved by bonding with the CH group contained in the sponge-like porous body. Therefore, the oxide film may contain C (carbon). In the sponge-like porous body of the present invention, C content in the oxide film is preferably 0.5 at % or more and 25 at % or less (0.5 atomic % or more and 25 atomic % or less), whereby the sponge-like porous body can have sufficient hydrophilicity. Note that when the C content is less than 0.5 at %, detection by an analyzer is difficult, and when the C content is more than 25 at %, hydrophilicity is insufficient. The C content in the oxide film can be analyzed by XPS (X-ray photoelectron spectroscopy).

### Second Embodiment

The second embodiment relates to a method for producing a sponge-like porous body.

The method for producing a sponge-like porous body of the present invention includes: providing a substrate with pores; and forming a hydrophilic film on an inner wall of the pores by ALD (atomic layer deposition), wherein the substrate contains a foam resin; and the substrate contains at least one selected from the group consisting of polyurethane, polyether and polyethylene.

Hereinafter, each step will be described. Since the substrate itself is as described above, the description thereof is omitted.

### (Providing Step)

The method for producing a sponge-like porous body of the present invention includes providing a substrate with pores. The method of producing the substrate is not particularly limited as long as the desired flexibility and elasticity (hardness) can be obtained, and the following known methods can be used: A curing agent and hollow particles (such as resin balloons) are, for example, mixed in polyurethane and cured, followed by heat treatment to expand the hollow particles, thereby producing a sponge-like porous body. A chemical foaming agent dispersed in polyurethane is decomposed by heat, and bubbles are generated by the generated gas to produce a sponge-like porous body. In addition, a curing agent is, for example, added after production of a W/O type emulsion of polyurethane and water, and then water and air are replaced after curing to produce a sponge-like porous body.

For example, a curing agent is added by kneading salt into polyurethane. After molding, the salt is dissolved away with water or other media to produce a sponge-like porous body. Another example is that a curing agent is added after dispersing a chemical foaming agent in polyurethane, heated to decompose the chemical foaming agent and then generate bubbles by generated gas to produce a sponge-like porous body. Moreover, a curing agent is, for example, added after dissolving gas into polyurethane by applying pressure and then subjected to foaming by the pressure of the gas generated by decompression to produce a sponge-like porous body. Although polyurethane is mentioned as an example, production methods can also be applied to polyether, polyethylene and other resins. The substrate preferably contains at least one selected from the group consisting of polyurethane, polyether and polyethylene and more preferably polyurethane. The substrate preferably contains a foam resin. As a result, a flexible and elastic sponge-like porous body can be produced.

In the providing step of the present invention, the substrate may be provided by the above-described preparation method, or a substrate such as a ready-made product may be provided.

### (Film Forming Step)

The method for producing a sponge-like porous body of the present invention includes forming a hydrophilic film on an inner wall of pores by ALD (atomic layer deposition). The method for producing a sponge-like porous body of the present invention includes a film forming step after the providing step. Examples of a method of applying a hydrophilic film having a uniform film thickness from a front surface portion to an inside of the sponge-like porous body include ALD (atomic layer deposition) described later. ALD supplies a film material in a form of a gas, thereby forming the film within a range where a gaseous material can reach. In addition, ALD is a method of stacking atomic layers one by one, enabling the films to have uniform thickness regardless of a shape and location of the substrate. As a result, a sponge-like porous body having hydrophilic properties from a front surface portion to an inside can be produced.

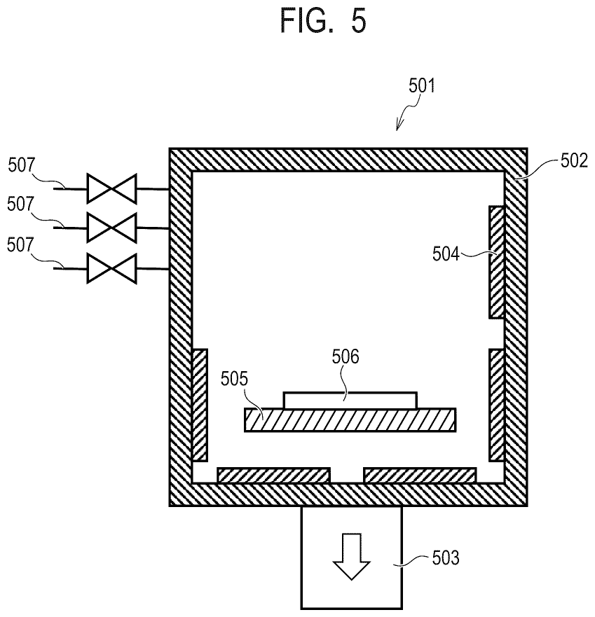

In the second embodiment, a method of forming a hydrophilic film on an inner wall of pores of the sponge-like porous body will be described. ALD (atomic layer deposition) can be used to form the hydrophilic film. FIG. 5 illustrates a schematic view of an ALD film forming apparatus. An ALD film forming apparatus 501 is equipped with an exhaust unit 503 for vacuuming an inside of a chamber, a heater 504 for heating the substrate, and a plurality of gas supply units 507 to attach a film to a substrate 506 on a substrate holder 505.

The film formation procedure is as follows:
(Procedure 1) The substrate 506 is installed and evacuated;
(Procedure 2) The substrate 506 is heated to a predetermined temperature by the heater 504;
(Procedure 3) A precursor is supplied through the gas supply unit 507;
(Procedure 4) A noble gas such as Ar is introduced through the gas supply unit 507 to purge (excess of the precursor is excluded);
(Procedure 5) A reactive gas such as H₂O and O₂ is supplied through the gas supply unit 507 to oxidize the film;
(Procedure 6) A noble gas such as Ar is introduced through the gas supply unit 507 to purge;
(Procedure 7) When the procedures 3 to 6 are regarded as one cycle, a film having a thickness of one atomic layer (thickness of approximately 0.1 to 1.0 nm) is formed in one cycle, and the cycle is thus repeated until a desired film thickness is obtained; and
(Procedure 8) The vacuum chamber 502 is opened to an atmosphere to take out the substrate 506.

### (Through Hole Forming Step)

In the method for producing a sponge-like porous body of the present invention, the providing step described above preferably includes forming a through hole in the substrate, whereby a sponge-like porous body having hydrophilic properties from a front surface portion to an inside can be produced even if the sponge-like porous body has discontinuous holes (in a case where the holes are not connected to each other).

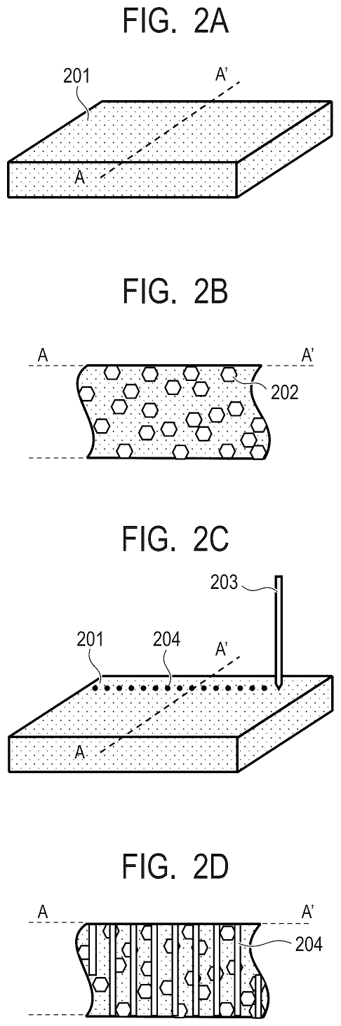

The sponge-like porous body can be roughly classified into an open-cell type and a closed-cell type. In the open-cell type, pores inside the sponge-like porous body are connected to the adjacent pores, whereas in the closed-cell type, some of the pores are not connected to the adjacent pores and are spatially isolated. In the formation of a film on these sponge-like porous bodies by ALD, it is considered that a gaseous material spreads to almost all the pores in the open-cell type but does not reach some of the pores in the closed-cell type. Therefore, when applying the second embodiment to the closed-cell type sponge-like porous body, it is preferable to go through steps as illustrated in FIGS. 2C and 2D.

FIG. 2A is a perspective view of a sponge-like porous body (closed-cell type) according to an embodiment of the present invention, while FIG. 2B is a schematic view of a cross-section taken along a line A-A′ of FIG. 2A. FIG. 2C is a schematic view showing a vertical hole being made in a sponge-like porous body with a needle, while FIG. 2D is a schematic view of a cross-section taken along a line A-A′ of FIG. 2C after a vertical hole is made in the sponge-like porous body with a needle. A vertical hole (through-hole) 204 is made in a closed-cell type sponge-like porous body 201 as illustrated in FIGS. 2A and 2B by using a needle 203 as illustrated in FIGS. 2C and 2D. Thereafter, when a hydrophilic film is formed by a method such as ALD, the hydrophilic film can be attached to pores 202 inside the sponge-like porous body. The vertical hole (through-hole) 204 is not necessarily a hole penetrating from the front surface to the back surface of the sponge-like porous body and may be a hole connecting the pores 202 to each other to an extent that an inside of the sponge-like porous body can have a hydrophilic film.

### Application Example

Hereinafter, an application example in which the sponge-like porous body shown in the first embodiment is used will be described in detail.

### (Polishing Pad)

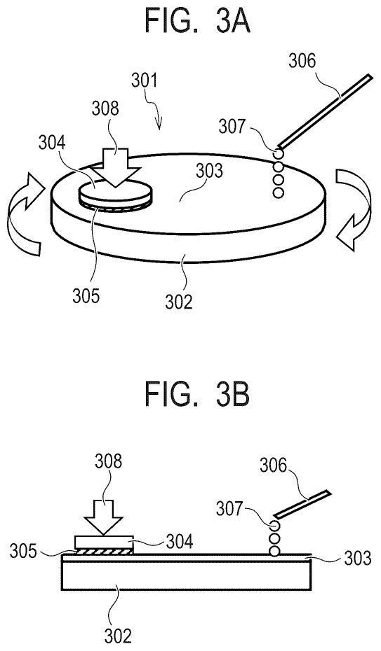

The polishing pad of the present invention preferably has the sponge-like porous body of the present invention. FIGS. 3A and 3B illustrate the case where the sponge-like porous body of the application example is used as a polishing pad. FIG. 3A is a schematic perspective view showing a CMP polishing apparatus 301, and FIG. 3B is a side view of FIG. 3A. CMP stands for Chemical Mechanical Polishing, which is a polishing technique frequently used in the semiconductor manufacturing process. In FIGS. 3A and 3B, a polishing object (workpiece) is described as a silicon wafer, but not limited thereto. In CMP, a silicon wafer 305 as a workpiece is brought into contact with a polishing pad 303 by applying a load 308.

In the polishing pad of the present invention, the front surface portion is preferably used as a polishing surface for polishing an object to be polished using a polishing liquid. Then, a stage 302 is rotated while dripping a polishing liquid 307 from a polishing liquid supply unit 306, and a silicon wafer 305 and a polishing pad 303 slide on each other to polish the silicon wafer 305 fixed to a workpiece holding member 304. As the polishing pad 303, the sponge-like porous body of the application example may be used alone or in a stack of a plurality of pads. A thickness of the polishing pad 303 is not limited and is approximately 0.1 to 2.0 mm, more preferably approximately 0.4 to 0.8 mm. Furthermore, the polishing pad 303 is not limited to the sponge-like porous body of the application example alone, and an intermediate layer such as a substrate or a cushion layer may be bonded to an opposite side of a polishing surface of the sponge-like porous body.

In the sponge-like porous body of the present invention, a glass polishing rate before an accelerated test for durability is preferably 0.70 μm/min or more in a section of “(Evaluation of Polishing Rate and Polishing Rate Stability)” and Table 1 described later. In the sponge-like porous body of the present invention, a glass polishing rate after the accelerated test for durability is preferably 0.70 μm/min or more. In the sponge-like porous body of the present invention, the value obtained by dividing the glass polishing rate after the accelerated test for durability by the glass polishing rate before the accelerated test for durability is preferably 0.70 or more.

The sponge-like porous body of the present invention preferably has a wear rate of 0.40 μm/min or less in an accelerated test for durability in the section of “(Evaluation of Polishing Pad Durability)” and Table 1 described later.

Thus, the sponge-like porous body can be suitable as a polishing pad. The polishing pad of an application example has a higher polishing effect than the polishing pad to which the sponge-like porous body of the present invention is not applied, and has an effect of maintaining properties as a polishing pad even if the polishing pad is worn to some extent.

### (Liquid Absorbing Pad)

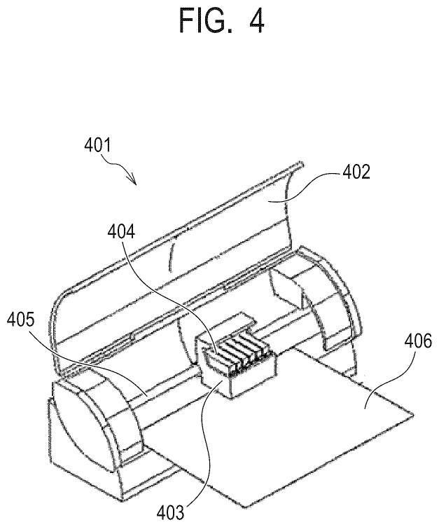

Subsequently, a case where the sponge-like porous body of the application example is used as a liquid absorbing pad (e.g., an ink absorbing pad) will be described. The liquid absorbing pad of the present invention preferably has the sponge-like porous body of the present invention. FIG. 4 illustrates a schematic perspective view of a general inkjet printer. When a printer cover 402 is opened, an inkjet head 403 with ink tanks 404 of a plurality of colors attached is held by a shaft 405. An inkjet printer 401 draws a desired image on the paper surface by ejecting ink onto paper 406 while moving the inkjet head 403 along the shaft 405.

An inkjet printer often requires preliminary ejection. If the printer is not used for a long time, ink at a nozzle tip of the head inevitably becomes dry and thickened, resulting in unstable ejection. To prevent such instability, a certain amount of ink is ejected before a start of drawing to refresh the printer. In the preliminary ejection, unnecessary ink is ejected toward an ink absorbing pad. In this case, the ink absorbing pad is required to have high ink holding force because any ink bounce or leakage of ink from the ink absorbing pad will adversely affect subsequent drawing. The sponge-like porous body of the application example has high hydrophilicity and thus can be used as the ink absorbing pad.

### (Cleaning Sponge)

Furthermore, the sponge-like porous body of the application example can be used as a cleaning sponge. The cleaning sponge of the present invention preferably has the sponge-like porous body of the present invention. The cleaning sponge as used herein includes a water-absorbing sponge for wiping off moisture from tableware, an automobile, or a human body in addition to a sponge for dishwashing, a car washing sponge for washing an automobile etc., a body sponge for washing a human body. These cleaning sponges have an effect of firmly retaining moisture and detergent (shampoo) and improving foam retention by increasing the hydrophilicity properties. In a case of the water-absorbing sponge, a water-absorbing performance also enhanced.

### (Cultivation Sponge)

Finally, the sponge-like porous body of the application example can be used as a sponge for hydroponic cultivation. The cultivation sponge of the present invention preferably has the sponge-like porous body of the present invention. Water and nutrients can be efficiently supplied to plants by enhancing the hydrophilic properties of a sponge for hydroponic cultivation.

### EXAMPLES

The present invention is described in detail below with reference to Examples and Comparative Examples. Note that the scope of the present invention is not limited to such Examples.

### Example 1

Polyurethane (Coronate 4370, manufactured by Tosoh Corporation) was used as a resin material, a curing agent (Nippollan 4479, manufactured by Tosoh Corporation) was selected accordingly, and hollow particles (Matsumoto Microsphere FN-78D, manufactured by Matsumoto Yushi-Seiyaku Co., Ltd) were blended therein. This formulation is placed in a polishing pad mold of square 200×200 mm (200×200 mm²) and pre-cured in an oven at 120° C. for 10 minutes. After primary curing at 120° C. for 2 hours, a polishing pad was released from the mold and subjected to secondary curing at another 120° C. for 8 hours. In this case, a thickness of the polishing pad was 1.5 mm.

A film containing SiO₂ (hydrophilic film) was formed on the polishing pad obtained above by ALD. 3DMAS was used as a precursor and H₂O as a reactive gas to form SiO₂ having a thickness of about 100 nm.

### Example 2

A same procedure as in Example 1 was performed, except that the thickness of the film containing SiO₂ was adjusted to about 10 nm.

### Example 3

A same procedure as in Example 1 was performed, except that the film containing SiO₂ was changed to a film containing Al₂O₃ (hydrophilic film), TMA was used as the precursor and H₂O as the reactive gas, and the film thickness was adjusted to about 100 nm.

### Example 4

A same procedure as in Example 3 was performed, except that the thickness of the film containing Al₂O₃ was adjusted to about 10 nm.

### Example 5

A same procedure as in Example 1 was performed, except that the C content in the film containing SiO₂ was reduced (1.0 at %), and the film containing SiO₂ with a low C content was formed using ozone instead of H₂O as the reactive gas.

### Example 6

A same procedure as in Example 1 was performed, except that the C content in the film containing SiO₂ was increased (23.4 at %), and the film containing SiO₂ with a high C content was formed by reducing an amount of H₂O supplied as the reactive gas.

### Comparative Example 1

A simple polyurethane polishing pad was used. A preparation method was a same as in a first half of Example 1 above, and no film containing SiO₂ was formed.

### Comparative Example 2

A polishing pad prepared by mixing polyurethane with a hydrophilic polymer (epoxy resin) was used. A same procedure as in a first half of Example 1 (other than film formation) was performed, except that polyurethane (Coronate 4370, manufactured by Tosoh Corporation) and epoxy resin (JER834, manufactured by Mitsubishi Chemical Corporation) were mixed at a ratio of 7:3, and a curing agent (jERCURE FL052, manufactured by Mitsubishi Chemical Corporation) was selected accordingly and blended therein.

### Comparative Example 3

In a same manner as in Comparative Example 2, a polishing pad prepared by mixing polyurethane with a hydrophilic polymer (epoxy resin) was used. An only difference from Comparative Example 2 was that the mixing ratio of polyurethane to epoxy resin was 5:5.

### Comparative Example 4

A polyurethane polishing pad having a surface sprayed with a hydrophilic resin was used. The polishing pad described in Comparative Example 2, which had been coated with a hydrophilic spray (MAGI-Poly®, manufactured by Crystal Optics Inc.), was used.

Table 1 shows the evaluation result of each sample. The present Examples achieve both a polishing rate and durability as compared with Comparative Examples (the determination of each Example is A or B).

TABLE 1

| | | Thickness (mm) of | | Contact angle (deg) | | | |
|---|---|---|---|---|---|---|---|
| | Hardness | polishing pad | Contact angle | after approximately | | | |
| | (Type A | (sponge-like | (deg) before wear | 100 μm wear of | D1 | D2 | C content (at %) |
| | durometer) | porous body) | of polishing pad | polishing pad | (nm) | (nm) | in oxide film |
| Example 1 | 66.2 | 1.5 | 91 | 93 | 98 | 99 | 12.3 |
| Example 2 | 65.4 | 1.5 | 97 | 95 | 11 | 10 | 11.6 |
| Example 3 | 67.9 | 1.5 | 102 | 101 | 103 | 101 | 14.2 |
| Example 4 | 67.1 | 1.5 | 105 | 106 | 10 | 10 | 15.1 |
| Example 5 | 66.4 | 1.5 | 89 | 88 | 101 | 102 | 1.0 |
| Example 6 | 66.0 | 1.5 | 110 | 109 | 104 | 103 | 23.4 |
| Comparative | 65.8 | 1.5 | 115 | 114 | — | 0 | — |
| Example 1 | | | | | | | |
| Comparative | 86.7 | 1.5 | 107 | 109 | — | 0 | — |
| Example 2 | | | | | | | |
| Comparative | 93.4 | 1.5 | 99 | 99 | — | 0 | — |
| Example 3 | | | | | | | |
| Comparative | 71.1 | 1.5 | 88 | 116 | — | 0 | — |
| Example 4 | | | | | | | |

| | Polishing rate (before | | Polishing rate (after | | Polishing rate stability | | Durability | |
|---|---|---|---|---|---|---|---|---|
| | durability test) | | durability test) | | Rate | | Wear | |
| | Rate | | Rate | | ratio | | rate | |
| | (μm/min) | Evaluation | (μm/min) | Evaluation | R | Evaluation | (μm/min) | Evaluation |
| Example 1 | 1.26 | A | 1.24 | A | 0.98 | A | 0.14 | A |
| Example 2 | 1.17 | A | 1.18 | A | 1.01 | A | 0.13 | A |
| Example 3 | 1.04 | A | 1.04 | A | 1.00 | A | 0.14 | A |
| Example 4 | 0.89 | B | 0.87 | B | 0.98 | A | 0.15 | A |
| Example 5 | 1.29 | A | 1.26 | A | 0.98 | A | 0.13 | A |
| Example 6 | 0.74 | B | 0.77 | B | 1.04 | A | 0.14 | A |
| Comparative | 0.53 | C | 0.56 | C | 1.06 | A | 0.12 | A |
| Example 1 | | | | | | | | |
| Comparative | 0.78 | B | 0.76 | B | 0.97 | A | 0.41 | C |
| Example 2 | | | | | | | | |
| Comparative | 1.12 | A | 1.09 | A | 0.97 | A | 0.56 | C |
| Example 3 | | | | | | | | |
| Comparative | 1.32 | A | 0.47 | C | 0.36 | C | 0.17 | A |
| Example 4 | | | | | | | | |

The methods of measurement and evaluation carried out above will be described.

### (Measurement of Hardness)

A hardness of the polishing pad was measured using a Type A durometer (ASKER Rubber Hardness Tester Type A, manufactured by KOBUNSHI KEIKI CO., LTD.). A detailed measurement method was according to Japanese Industrial Standards JIS K 7215.

### (Measurement of Contact Angle)

A hydrophilicity of the polishing pad was quantified in terms of contact angle. The contact angle before wear of the polishing pad and the contact angle after approximately 100 μm wear of the polishing pad was measured. The contact angle was measured using a contact angle meter (DropMaster DM300, manufactured by Kyowa Interface Science Co., Ltd.) when 2 μL of pure water was dripped on the polishing pad. A detailed measurement method was according to Japanese Industrial Standard JIS R 3257.

### (Measurement of Film Thickness (Measurement of D1 and D2))

An average thicknesses D1 and D2 of the hydrophilic film were measured as follows: First, the sponge-like porous body was cut out into a square of 10 mm×10 mm when viewed from a top. In order to evaluate D1, the sponge-like porous body was then sliced at 10% of a thickness of a sponge-like porous body in the thickness direction from the front surface portion to the back surface portion of the sponge-like porous body to obtain a cross-section. Furthermore, in order to evaluate D2, the sponge-like porous body was then sliced at 50% of a thickness of the sponge-like porous body in the thickness direction from the front surface portion to the back surface portion of the sponge-like porous body to obtain a cross-section. The cross-sectioned sample was observed through a scanning electron microscope (JSM-IT500HR, manufactured by JEOL Ltd.) to measure a thickness of the hydrophilic film on the inner wall of the pores present in the cross-section. When 50% or more of the pores in the cross-section had a hydrophilic film as a result of an observation of a cross-section with scanning electron microscope, a thickness of a hydrophilic film was measured with 20 pores having a hydrophilic film for each cross-section, and the average values were denoted as D1 and D2. When less than 50% of the pores in the cross-section had a hydrophilic film, the values of D1 and D2 were set to 0.

### (Measurement of C Content)

Regarding measurement of the C content (carbon content) of the oxide film in the pores of the polishing pad, separately, a Si wafer on which a film was formed under same conditions and with a same thickness was provided, and the film formed on the Si wafer was analyzed by XPS (X-ray photoelectron spectrometer) (QuanteraII, manufactured by ULVAC-PHI, Inc.) to measure the C content.

### (Evaluation of Polishing Rate and Polishing Rate Stability)

An evaluation of the polishing rate with the polishing pad was carried out. A glass was polished for a predetermined time, and a weight of the glass before and after polishing was measured. The polishing rate was calculated from a decrease in glass weight. An apparatus shown in FIGS. 3A and 3B was used for polishing, and polishing conditions were as shown below.
Workpiece: S-FSL5 (Ohara Inc.), $50
Load applied to workpiece: 25 kPa
Rotational speed of stage: 500 rpm
Polishing time: 30 minutes
Abrasive: cerium oxide (MIREK® K30-9, manufactured by Mitsui Mining & Smelting Co. Ltd.)

The polishing rate was evaluated by two conditions, i.e., one condition when the polishing pad was new (before the accelerated test for durability), and another condition when the polishing pad was worn by approximately 100 μm in an accelerated test for durability of the polishing pad to be described later (after the accelerated test for durability). A polishing rate stability was evaluated by comparing the two conditions.

The polishing rate was evaluated as follows, and the evaluation of the polishing rate is preferably B or higher.
A: 1.00 μm/min or more
B: 0.70 μm/min or more and less than 1.00 μm/min
C: less than 0.70 μm/min

Regarding the polishing rate stability, a rate ratio R was defined as follows to evaluate stability based on a value of R, and the evaluation of the polishing rate stability is preferably B or higher.

$$R = Polishing rate in worn state / polishing rate in new state \\ A : R \geq 0.85 \\ B : 0.7 \leq R < 0.85 \\ C : R < 0.70$$

### (Evaluation of Polishing Pad Durability)

The durability of the polishing pads was evaluated by conducting an accelerated test for durability. The accelerated test for durability as used in the present invention refers to a test conducted using an apparatus shown in FIGS. 3A and 3B, in which diamond pellets are used in the workpiece to create a situation where the polishing pad is worn at an accelerated rate by the diamond pellets. The wear rate was taken as the durability of the polishing pad. Wear conditions are as follows.
Workpiece: diamond pellet, #1200
Load applied to workpiece: 4 kPa
Rotational speed of stage: 110 rpm
Wear time: 30 minutes

Regarding the durability of the polishing pad, the following criteria were evaluated based on the wear rate of the polishing pad when evaluated by the above method. The durability of the polishing pad is preferably B or higher.
A: wear rate of polishing pad≤0.20 μm/min
B: 0.20 μm/min<wear rate of polishing pad≤0.40 μm/min
C: 0.40 μm/min<wear rate of polishing pad

As described above, the sponge-like porous body of the present invention can improve hydrophilic properties to an inside of the porous body without impairing the elasticity and flexibility of the sponge-like porous body.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application No. 2023-168638, filed Sep. 28, 2023, which is hereby incorporated by reference herein in its entirety.

What is claimed is:

1. A sponge-like porous body comprising a substrate with pores, wherein
an inner wall of the pores has a hydrophilic film in a region from a depth of 0% to a depth of 20% or more of a thickness of the sponge-like porous body in a thickness direction from a front surface portion to a back surface portion; and
the substrate comprises a foam resin.

2. The sponge-like porous body according to claim 1, wherein the hydrophilic film is an oxide film.

3. The sponge-like porous body according to claim 2, wherein a material of the oxide film comprises one or a mixture of two or more selected from the group consisting of SiO₂, Al₂O₃, TiO₂, Ta₂O₅, HfO₂ and RuO₂.

4. The sponge-like porous body according to claim 2, wherein a C content in the oxide film is 0.5 at % or more and 25 at % or less.

5. The sponge-like porous body according to claim 1, wherein the substrate comprises at least one selected from the group consisting of polyurethane, polyether and polyethylene.

6. The sponge-like porous body according to claim 1, wherein the substrate comprises polyurethane.

7. The sponge-like porous body according to claim 1, wherein, when an average thickness of the hydrophilic film on the inner wall of the pores in a region at a depth of 0% or more and 20% or less of the thickness of the sponge-like porous body in the thickness direction from the front surface portion to the back surface portion is denoted as D1, and an average thickness of the hydrophilic film on the inner wall of the pores in a region (a center portion) at a depth of 40% or more and 60% or less of the thickness of the sponge-like porous body in the thickness direction from the front surface portion to the back surface portion is denoted as D2, D1 and D2 satisfy all of the following inequalities:
$$10 nm \leq D 1 \leq 10 μm , 10 nm \leq D 2 \leq 10 μm , and \\ 0.7 \times D 2 \leq D 1 \leq 1.3 \times D 2.$$

8. The sponge-like porous body according to claim 1, having a hardness of 90 points or less as measured by a Type A durometer.

9. The sponge-like porous body according to claim 1, having a thickness of 0.1 mm or more.

10. The sponge-like porous body according to claim 1, having a thickness of 0.5 mm or more.

11. The sponge-like porous body according to claim 1, wherein the substrate comprises a foam resin.

12. A polishing pad comprising a sponge-like porous body having a substrate with pores, wherein, in the sponge-like porous body,
an inner wall of the pores has a hydrophilic film in a region from a depth of 0% to a depth of 20% or more of a thickness of the sponge-like porous body in a thickness direction from a front surface portion to a back surface portion; and wherein
the front surface portion is used as a polishing surface for polishing an object to be polished with a polishing liquid.

13. The polishing pad according to claim 12, wherein a polishing rate of glass before an accelerated test for durability is 0.70 μm/min or more.

14. The polishing pad according to claim 12, wherein a polishing rate of glass after an accelerated test for durability is 0.70 μm/min or more.

15. The polishing pad according to claim 12, wherein a value obtained by dividing a polishing rate of glass after an accelerated test for durability by a polishing rate of glass before an accelerated test for durability is 0.70 or more.

16. The polishing pad according to claim 12, wherein a wear rate is 0.40 μm/min or less in an accelerated test for durability.

17. A liquid absorbing pad comprising a sponge-like porous body having a substrate with pores, wherein, in the sponge-like porous body,
an inner wall of the pores has a hydrophilic film in a region from a depth of 0% to a depth of 20% or more of a thickness of the sponge-like porous body in a thickness direction from a front surface portion to a back surface portion; and
the substrate comprises a foam resin.

18. A cleaning sponge comprising a sponge-like porous body having a substrate with pores, wherein, in the sponge-like porous body,
an inner wall of the pores has a hydrophilic film in a region from a depth of 0% to a depth of 20% or more of a thickness of the sponge-like porous body in a thickness direction from a front surface portion to a back surface portion; and
the substrate comprises a foam resin.

19. A cultivation sponge comprising a sponge-like porous body having a substrate with pores, wherein, in the sponge-like porous body,
an inner wall of the pores has a hydrophilic film in a region from a depth of 0% to a depth of 20% or more of a thickness of the sponge-like porous body in a thickness direction from a front surface portion to a back surface portion; and
the substrate comprises a foam resin.

20. A method for producing a sponge-like porous body, comprising:
providing a substrate with pores; and
forming a hydrophilic film on an inner wall of the pores by atomic layer deposition (ALD),
wherein the substrate comprises at least one selected from the group consisting of polyurethane, polyether and polyethylene.

21. The method for producing a sponge-like porous body according to claim 20, wherein the providing comprises forming a through hole in the substrate.
